(19) United States
(12) Patent Application Publication
(10) Pub. No.: US 2011/0212613 A1
(43) Pub. Date: Sep. 1, 2011

(54) SEMICONDUCTOR DEVICES HAVING A FUSE AND METHODS OF CUTTING A FUSE

(76) Inventors: JEONG-KYU KIM, HWASEONG-SI (KR); KUN-GU LEE, SEOUL (KR)

(21) Appl. No.: 12/912,139

(22) Filed: Oct. 26, 2010

(30) Foreign Application Priority Data
Feb. 26, 2010 (KR) 10-2010-0017924

(51) Int. Cl. H01L 21/768

(52) U.S. Cl. 438/601; 257/E21.592

(57) ABSTRACT

A semiconductor device and methods of cutting a fuse of a semiconductor device are provided, the semiconductor device includes a semiconductor substrate that includes a fuse region, a plurality of fuse patterns disposed in the fuse region of the semiconductor substrate, and an insulating layer that insulates the fuse patterns from the semiconductor substrate. The fuse patterns each include a fuse. The fuse patterns are linked to the semiconductor substrate.

### CROSS-REFERENCE TO RELATED APPLICATIONS

This application claims priority under 35 U.S.C. §119 from Korean Patent Application No. 10-2010-0017924, filed on Feb. 26, 2010, in the Korean Intellectual Property Office, the disclosure of which is incorporated herein in its entirety by reference.

### BACKGROUND

1. Field

Example embodiments of the inventive concepts relate to semiconductor devices and methods of manufacturing the same, and more particularly, to semiconductor devices having a fuse and methods of cutting the fuse of the semiconductor device.

2. Related Art

With the high integration of semiconductor devices and increase in capacities of the semiconductor devices, defects may occur more often in memory cells in processes of manufacturing the semiconductor devices, lowering the product manufacturing yield. A technique of using a redundancy circuit for replacing a defective main cell of a semiconductor device is one type of technique used to increase a yield that is lowered due to the high integration of semiconductor devices and has been widely used.

The redundancy circuit replaces a defective cell with another cell by cutting a corresponding fuse in a fuse region formed in a peripheral region of the semiconductor device using a laser repair process. In other words, when a test apparatus detects a defective main cell through a set test, the redundancy circuit replaces the defective main cell with a redundancy cell formed around the defective main cell by cutting the corresponding fuse in the fuse region. Fuses in the fuse region are selectively cut according to results of the set test, performed with respect to the semiconductor device. Cutting of the fuses may be performed by irradiating a laser beam thereon (e.g., by blowing a laser). In other words, the fuses are cut using a laser beam having a uniform spot size in a laser repair process for replacing a defective cell via a normal redundancy circuit.

Sizes of fuses of a semiconductor device and pitches among the fuses have decreased as semiconductor devices become more highly integrated. Therefore, when a laser beam is used to cut a fuse, the laser beam may damage a fuse adjacent to the fuse to be cut, the laser beam may fail to cut the fuse, or the laser beam may damage a semiconductor structure positioned under the fuse.

### SUMMARY

Example embodiments of the inventive concepts relate to semiconductor devices and methods of manufacturing the same, and more particularly, to semiconductor devices having a fuse and methods of cutting a fuse of the semiconductor device.

Example embodiments of the inventive concepts provide a semiconductor device having a plurality of fuses, in which although pitches among the fuses are small, a semiconductor structure positioned under the fuse is not damaged when a laser beam is irradiated thereon, and a method of cutting the fuse of the semiconductor device.

According to example embodiments of the inventive concepts, there is provided a semiconductor device including a semiconductor substrate that includes a fuse region, a plurality of fuse patterns disposed in the fuse region of the semiconductor substrate and including fuses, and an interlayer insulating layer that insulates the fuse patterns from the semiconductor substrate, wherein the fuse patterns are linked to the semiconductor substrate.

An active region may be formed in the semiconductor substrate. The fuse patterns are linked to the active region. The fuse patterns may be linked to the semiconductor substrate through contact plugs formed in the interlayer insulating layer. The fuse patterns may be disposed parallel with one another in a first direction in the fuse region of the semiconductor substrate and are spaced apart from one another in a second direction perpendicular to the first direction.

The fuses included in the fuse patterns may be adjacent to one another and parallel with one another in the second direction. The fuses included in the fuse patterns may not be directly adjacent to one another in the second direction. For example, the fuses may be disposed in a zigzag form.

According to example embodiments of the inventive concepts, there is provided a semiconductor device including a first interlayer insulating layer formed on a semiconductor substrate, contact plugs formed in the first interlayer insulating layer, fuse patterns formed on the first interlayer insulating layer and including fuses, and a second interlayer insulating layer formed on the fuse patterns and including fuse openings for exposing the fuses, wherein the fuse patterns are linked to the semiconductor substrate through the contact plugs.

An active region may be formed in the semiconductor substrate. The fuse patterns are linked to the active region. The fuse patterns may be formed as first metal patterns on the first interlayer insulating layer. The semiconductor device may further include an interlayer insulating layer formed on the first metal patterns, wherein the fuse patterns are formed as second metal patterns on the interlayer insulating layer. The fuse patterns may be formed as the first metal patterns, the second metal patterns, or the first and second metal patterns.

According to example embodiments of the inventive concepts, there is provided a method of cutting a fuse of a semiconductor device. A first interlayer insulating layer may be formed on a semiconductor substrate. A plurality of fuse patterns may be formed on the first interlayer insulating layer, wherein the plurality of fuse patterns include fuses which are linked to the semiconductor substrate. A second interlayer insulating layer may be formed on the fuse patterns, wherein the second interlayer insulating layer includes fuse openings that expose the fuses. When the fuse patterns are linked to the semiconductor substrate, laser beams may be irradiated onto the fuses through the fuse openings to cut the fuse patterns or the fuses.

An active region may be formed in the semiconductor substrate, wherein the fuse patterns are linked to the active region. The fuse patterns may be formed as metal patterns formed on the first interlayer insulating layer. The method may further include forming an interlayer insulating layer on first metal patterns, wherein the fuse patterns are formed as second metal patterns on the interlayer insulating layer. The fuse patterns may be formed as the first metal patterns, the second metal patterns, or the first and second metal patterns.

The fuse patterns may be linked to the semiconductor substrate through contact plugs formed in the first interlayer insulating layer. The fuse patterns may be disposed parallel with one another in a first direction in a fuse region of the semiconductor substrate and may be spaced apart from one another in a second direction perpendicular to the first direction. The fuses included in the fuse patterns may be adjacent to one another and parallel with one another in the second direction. The fuses included in the fuse patterns may not directly adjacent to one another in the second direction and may be disposed in a zigzag form.

According to example embodiments of the inventive concepts, there is provided a method of cutting a fuse of a semiconductor device. The method includes forming a semiconductor substrate that includes a fuse region, forming a plurality of fuse patterns in the fuse region of the semiconductor substrate, each of the fuse patterns includes a fuse, forming an interlayer insulating layer that insulates the plurality of fuse patterns from the semiconductor substrate, and cutting one of the fuses by irradiating laser beams through the corresponding fuse opening when the plurality of fuse patterns are connected to the semiconductor substrate.

The plurality of fuse patterns may be connected to an active region in the semiconductor substrate.

A plurality of contact plugs may be formed in the interlayer insulating layer, wherein the plurality of fuse patterns are connected to the semiconductor substrate through the plurality of contact plugs.

### BRIEF DESCRIPTION OF THE DRAWINGS

Example embodiments of the inventive concepts will be more clearly understood from the following detailed description taken in conjunction with the accompanying drawings in which:

FIG. 1 is a schematic plan view of structures of main parts of a semiconductor device according to example embodiments of the inventive concepts;

FIGS. 2 and 3 illustrate a fuse region according to example embodiments of the inventive concepts;

FIG. 4 is a cross-sectional view taken along a line IV-IV of FIG. 3 illustrating profiles of laser beams for cutting a fuse;

FIG. 5 is a plan view of a fuse region according to example embodiments of the inventive concepts;

FIG. 6 is a cross-sectional view taken along a line VI-VI of FIG. 5;

FIG. 7 is a plan view of a fuse region according to example embodiments of the inventive concepts;

FIG. 8 is a cross-sectional view taken along a line VIII-VIII of FIG. 7;

FIG. 9 is a plan view of a fuse region according to example embodiments of the inventive concepts;

FIG. 10 is a cross-sectional view illustrating a method of cuffing a fuse of a semiconductor device according to example embodiments of the inventive concepts;

FIG. 11 is a cross-sectional view illustrating a comparative method of cutting a fuse of a semiconductor device;

FIG. 12 is a cross-sectional view illustrating a method of cutting a fuse of a semiconductor device according to example embodiments of the inventive concepts;

FIG. 13 is a cross-sectional view illustrating another comparative method of cutting a fuse of a semiconductor device;

FIGS. 14 through 18 are cross-sectional views illustrating a method of cutting a fuse of a semiconductor device according to example embodiments of the inventive concepts; and

FIG. 19 is a cross-sectional view illustrating a method of cutting a fuse of a semiconductor device according to example embodiments of the inventive concepts.

### DETAILED DESCRIPTION OF EXAMPLE EMBODIMENTS

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments of the inventive concepts relate to semiconductor devices and methods of manufacturing the same, and more particularly, to semiconductor devices having a fuse and methods of cutting a fuse of the semiconductor device.

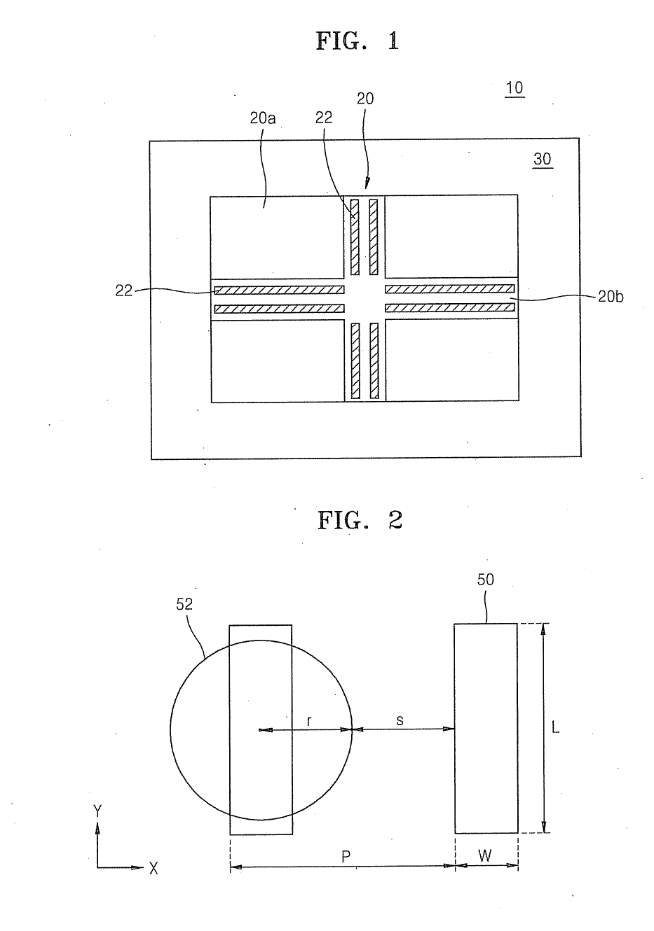

FIG. 1 is a schematic plan view of structures of main parts of a semiconductor device according to example embodiments.

Referring to FIG. 1, the semiconductor device (e.g., a dynamic random access memory (DRAM) device) includes a chip region 20 formed on a semiconductor substrate 10 (e.g., a wafer) and a scribe line region 30 formed around the chip region 20. The chip region 20 includes a cell region 20a and a peripheral circuit region 20b. Memory cells corresponding to a capacity of a memory are formed in the memory cell 20a. Peripheral circuits for driving unit cells of the cell region 20a (e.g., a decoder (not shown), a buffer circuit (not shown), a redundancy circuit (not shown), a fuse region 22, and the like) are formed in the peripheral circuit region 20b. The fuse region 22 will be described in more detail later.

FIGS. 2 and 3 illustrate a fuse region according to example embodiments of the inventive concepts.

In more detail, FIG. 2 illustrates a plurality of fuses 50 disposed in the fuse region 22, and a spot 52 of a laser beam irradiated onto one of the fuses 50. FIG. 3 illustrates a plurality of fuse patterns 48 disposed in the fuse region 22, and the fuses 50 included in the fuse patterns 48.

As shown in FIGS. 2 and 3, the fuse patterns 48 are disposed parallel with one another in a first direction (e.g., in a y-axis direction) in a fuse region 22 of a semiconductor substrate. The fuse patterns 48 are spaced apart from one another in a second direction perpendicular to the first direction (e.g., in an x-axis direction). The fuses 50 included in the fuse patterns 48 are adjacent to and parallel with one another in the second direction (i.e., in the x-axis direction).

Laser beams may be irradiated onto the fuses 50 to cut the fuse patterns 48. A laser beam may be irradiated onto one fuse 50 and may form the spot 52 having a radius “r” that is wider than a width “W” of the fuses 50 and shorter than a length “L” of the fuses 50. A diameter of the spot 52 of a laser beam is smaller than a pitch “P” between the fuses 50. In FIG. 2, a reference character “S” denotes a distance from the spot 52 of a laser beam formed on one fuse 50 to a side of a fuse 50 adjacent to the one fuse 50. In FIG. 3, a reference numeral 46 denotes an insulating layer that insulates the fuse patterns 48 from one another.

A pitch “P,” a width “W,” and a length “L” of fuses have decreased with the high integration of semiconductor devices. In particular, a pitch “P” between fuses may be less than 1.5 μm. Thus, when one fuse pattern 48 is cut by the spot 52 of a laser beam, a fuse pattern 48 adjacent to the fuse pattern 48 that is cut is damaged by the spot 52 of the laser beam. Therefore, the pitch “P,” the width “W,” and the length “L” of the fuses 50 are to be considered.

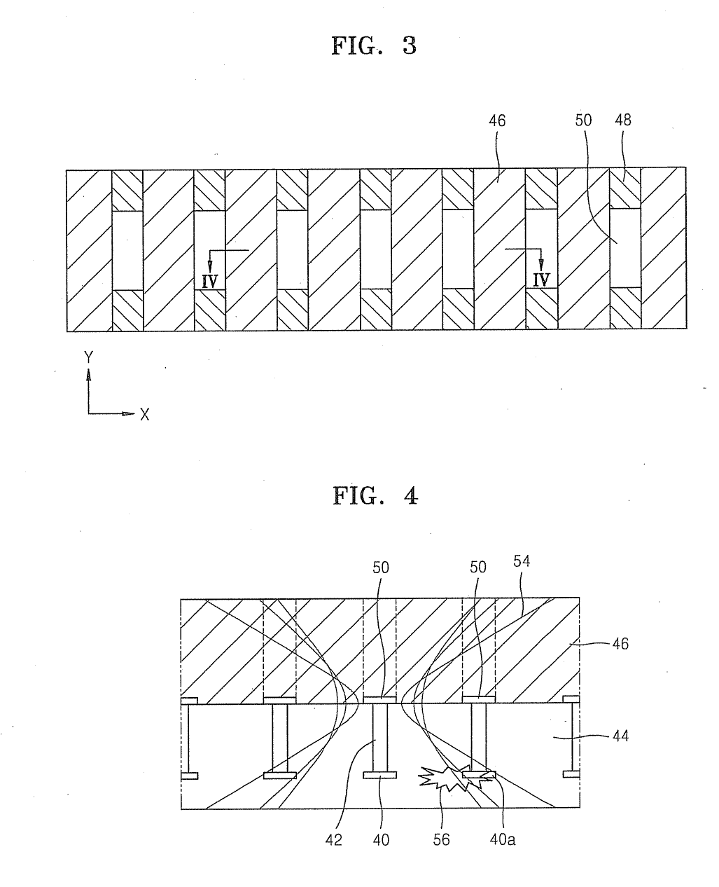

FIG. 4 is a cross-sectional view taken along a line IV-IV of FIG. 3 for illustrating profiles of laser beams for cutting a fuse.

In more detail, FIG. 4 illustrates a part of a semiconductor device formed on a semiconductor substrate (not shown). Reference numerals 44 and 46 denote insulating layers, and a reference numeral 42 denotes contact plugs. FIG. 4 is a cross-sectional view for illustrating that a semiconductor structure 40a may be damaged by laser beams having profiles 54 and irradiated onto fuses 50, as represented with a reference numeral 56.

Because a length “L” (of FIG. 2) of the fuses 50 decreases as the integration of the semiconductor device increases, the profiles 54 of the laser beams are curved (and not linear) when the fuse 50 positioned in the center (of FIG. 4) is cut. Therefore, the semiconductor structure 40a, which is adjacent to the fuse 50 positioned in the center and positioned above the semiconductor substrate (not shown) (e.g., a bit line) may be damaged. As a result, before one fuse 50 or a fuse pattern is cut by a laser beam, a consideration is to be made as to whether the semiconductor structure 40a adjacent to and positioned under the fuse 50 will be damaged.

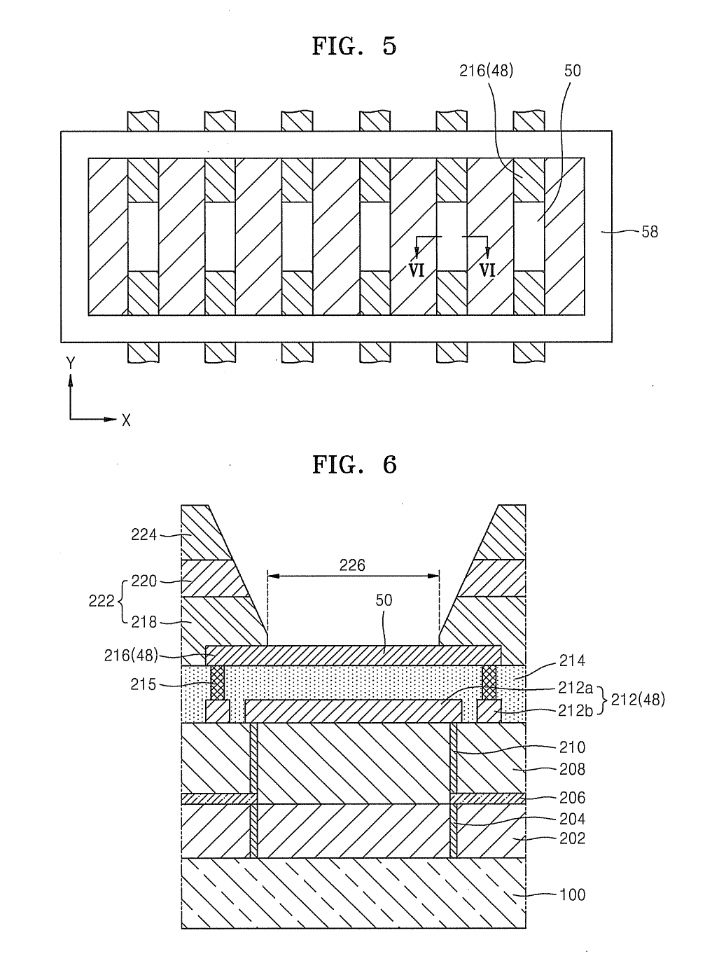

FIG. 5 is a plan view of a fuse region according to example embodiments of the inventive concepts. FIG. 6 is a cross-sectional view taken along a line VI-VI of FIG. 5.

Referring to FIGS. 5 and 6, like the fuse patterns 48 illustrated in FIG. 3, fuse patterns 48 are disposed parallel with one another in a first direction (e.g., a Y-axis direction) in a fuse region of a semiconductor substrate and are spaced apart from one another in a second direction perpendicular to the first direction (e.g., in an X-axis direction). Fuses 50 included in the fuse patterns 48 are adjacent to one another and parallel with one another in the second direction (i.e., in the X-axis direction). A guide ring 58 is disposed around the fuse patterns 48 and prevents an external region from being damaged when a laser beam is irradiated thereon. The guide ring 58 may be formed of a metal pattern.

Referring to FIG. 6, a semiconductor substrate 100 (i.e., a semiconductor wafer) is provided. The semiconductor substrate 100 may be, for example, a silicon substrate. The semiconductor substrate 100 includes an active region in which unit devices are to be formed. The semiconductor substrate 100 includes a well region formed in the active region. A first interlayer insulating layer 202 is formed on the semiconductor substrate 100. First contact plugs 204 are formed in the first interlayer insulating layer 202. The first interlayer insulating layer 202 insulates the first contact plugs 204 from one another.

A bit line 206 is formed on the first interlayer insulating layer 202. A second interlayer insulating layer 208 is formed on the bit line 206. Second contact plugs 210 are formed in the second interlayer insulating layer 208. The second interlayer insulating layer 208 insulates the second contact plugs 210 from one another. The first contact plugs 204 are connected to the second contact plugs 210. The first contact plugs 204 may be connected to the second contact plugs 210 through the bit line 206, or may be directly connected to the second contact plugs 210.

First metal patterns 212 are formed on the second interlayer insulating layer 208 and the second contact plugs 210. The first metal patterns 212 may be copper patterns or aluminum patterns. Each of the first metal patterns 212 includes two patterns 212a and 212b that are connected to each other. A third interlayer insulating layer 214 is formed on the first metal patterns 212. Third contact plugs 215 are formed in the third interlayer insulating layer 214 and connected to the first metal patterns 212. The third interlayer insulating layer 214 insulates the third contact plugs 215 from one another.

Second metal patterns 216 are formed on the third contact plugs 215 and the third interlayer insulating layer 214. The second metal patterns 216 may be copper patterns or aluminum patterns. The second metal patterns 216 may be the fuse patterns 48. The fuses patterns 48 include the fuses 50.

A passivation layer 222 and a polyimide layer 224 are formed on the fuse patterns 48 and the third interlayer insulating layer 214 and have fuse openings 226 that expose the fuses 50. The passivation layer 222 includes an oxide layer 218 and a nitride layer 220. The passivation layer 222 and the polyimide layer 224 may operate as insulating layers that protect a lower structure and insulate the fuse patterns 216 from one another.

In the semiconductor device shown in FIG. 6, the fuse patterns 48 are linked to the semiconductor substrate 100 (e.g., linked to the active region) through the third, second and first contact plugs 215, 210 and 204. As described above, laser beams are irradiated into the fuse openings 226 in a laser repair process to cut the fuses 50. Because a distance between each of the fuse patterns 48 and the semiconductor substrate 100 is relatively long (e.g., about 3 μm), a semiconductor structure positioned under the fuse patterns 48 (e.g., the first metal patterns 212, the bit line 206 or the like) may be inhibited from being damaged in a laser repair process.

If the distance between each of the fuse patterns 48 and the semiconductor substrate 100 is relatively long in the laser repair process, even with a laser beam irradiated onto the fuse patterns 48, a temperature of the semiconductor substrate 100 is less than 500° C. even though the fuse patterns 48 are linked to the semiconductor substrate 100. Although the fuse patterns 48 are linked to the semiconductor substrate 100 in the laser repair process, the semiconductor substrate 100 is not damaged. If laser beams are irradiated into the fuse openings 226 in the laser repair process to cut the second metal patterns 216 and the first metal patterns 212, the fuses 50 may be the second and first metal patterns 216 and 212.

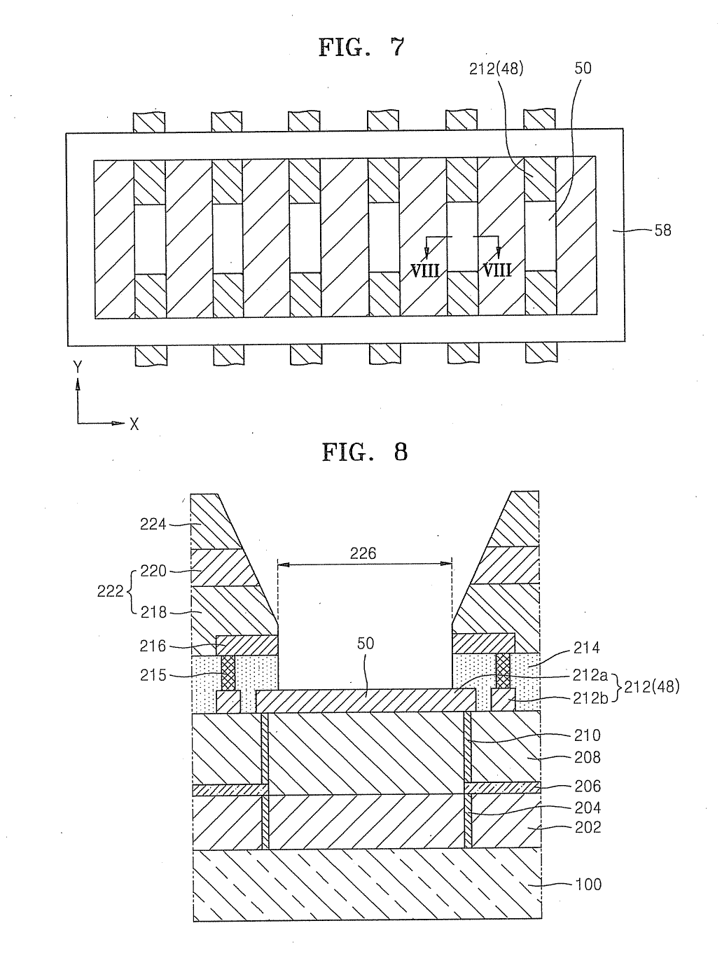

FIG. 7 is a plan view of a fuse region according to example embodiments of the inventive concepts. FIG. 8 is a cross-sectional view taken along a line VIII-VIII of FIG. 7.

In more detail, a fuse region of FIGS. 7 and 8 is the same as the fuse region of FIGS. 5 and 6 except that fuses 50 are formed as first metal patterns 212. Fuse patterns 48 of FIG. 7 are formed as the first metal patterns 212, which is different from the fuse patterns 48 of FIG. 5. An arrangement of the fuse patterns 48 of FIG. 7 is the same as that of the fuse patterns 48 of FIG. 3.

Referring to FIG. 8, the first metal patterns 212 are formed on a second interlayer insulating layer 208 and second contact plugs 210 that are formed above a semiconductor substrate 100. Each of the first metal patterns 212 includes two patterns 212a and 212b that are connected to each other. The first metal patterns 212 operate as the fuse patterns 48. A passivation layer 222 and a polyimide layer 224 that have fuse openings 226 exposing the fuses 50 are formed on the fuse patterns 48 and a third interlayer insulating layer 214.

In the semiconductor device shown in FIG. 8, the fuse patterns 48 are linked to the semiconductor substrate 100 (e.g., linked to an active region) through the second contact plugs 210 and first contact plugs 204. As described above, laser beams may be irradiated to the fuse openings 226 in a laser repair process to cut the fuses 50. Because a distance between each of the fuse patterns 48 and the semiconductor substrate 100 is relatively long in the laser repair process, the semiconductor substrate 100 is not damaged and a semiconductor structure under the fuse patterns 48 (e.g., a bit line 206 or the like) is inhibited from being damaged.

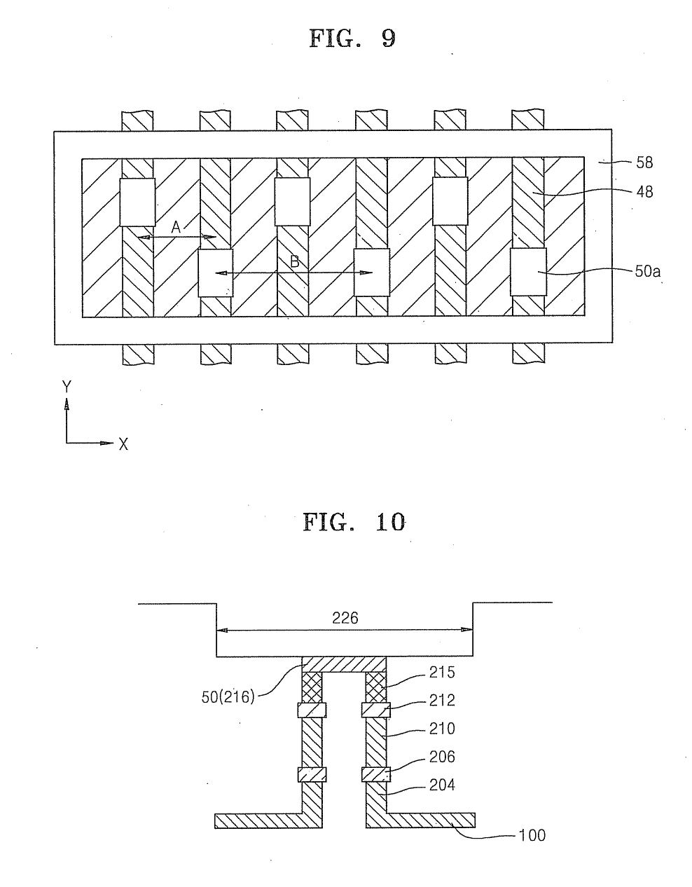

FIG. 9 is a plan view of a fuse region according to example embodiments of the inventive concepts.

Referring to FIG. 9, like the fuse patterns 48 illustrated in FIGS. 3, 5 and 7, fuse patterns 48 are disposed parallel with one another in a first direction (e.g., in a Y-axis direction) in a fuse region of a semiconductor substrate and are spaced apart from one another in a second direction perpendicular to the first direction (e.g., in an X-axis direction).

Different from the fuses 50 illustrated in FIGS. 3, 5 and 7, fuses 50a included in the fuse patterns 48 are not directly adjacent to one another but are disposed in a zigzag form in the second direction. A distance between the fuses 50 illustrated in FIGS. 3, 5 and 7 is represented with “A,” but a distance between the fuses 50a illustrated in FIG. 9 is represented with “B,” which is longer than “A.” Thus, when a laser beam cuts one fuse pattern 48, although a pitch between the fuses 50a may be less than 1.5 μm, a fuse pattern 48 adjacent to the fuse pattern 48 cut is inhibited from being damaged.

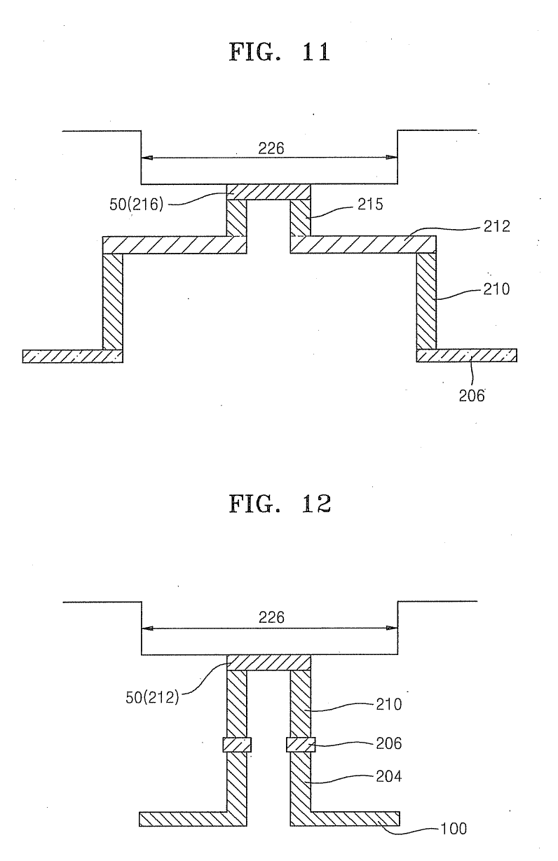

FIG. 10 is a cross-sectional view illustrating a method of cutting a fuse of a semiconductor device according to example embodiments of the inventive concepts. FIG. 11 is a cross-sectional view illustrating a comparative method of cutting a fuse of a semiconductor device.

Referring to FIG. 10, a second metal pattern 216 is formed as a fuse 50 (i.e., a fuse pattern 48), and the fuse 50 is linked to a semiconductor substrate 100 through contact plugs 215, 210 and 204, a first metal pattern 212, and a bit line 206. As described above, a laser beam may be irradiated onto the fuse 50 through a fuse opening 226 to cut the fuse 50. In a structure of the semiconductor device of FIG. 10, a distance between the fuse 50 and the semiconductor substrate 100 is relatively long, thereby inhibiting a semiconductor structure positioned under the fuse 50 (e.g., the bit line 206 or the like) from being damaged.

The semiconductor device of FIG. 11 has a structure in which a second metal pattern 216 is formed as a fuse 50 (i.e., a fuse pattern 48), and the fuse 50 is linked to a bit line 206 through contact plugs 215 and 210 and a first metal pattern 212. When a laser beam is irradiated into a fuse opening 226 to cut the fuse 50 in this case, a distance between the fuse 50 and the bit line 206 is relatively short, thereby damaging a semiconductor structure positioned under the fuse 50, (e.g., the bit line 206).

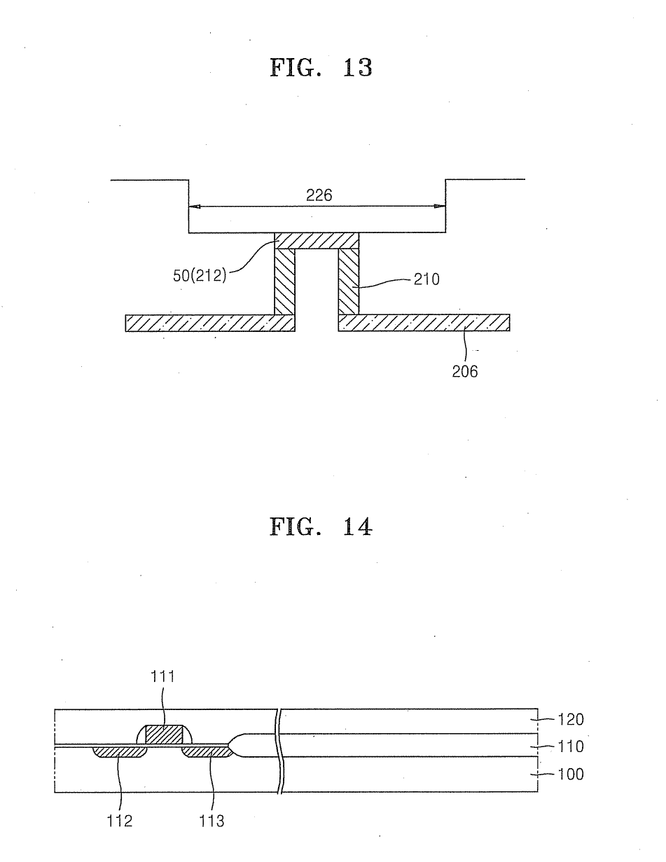

FIG. 12 is a cross-sectional view illustrating a method of cutting a fuse of a semiconductor device according to example embodiments of the inventive concepts. FIG. 13 is a cross-sectional view illustrating another comparative method of cutting a fuse of a semiconductor device.

Referring to FIG. 12, a first metal pattern 212 is formed as a fuse 50 (i.e., a fuse pattern 48), and the fuse 50 is linked to a semiconductor substrate 100 through contact plugs 210 and 204 and a bit line 206. As described above, a laser beam may be irradiated onto the fuse 50 through a fuse opening 226 to cut the fuse 50. In a structure of the semiconductor device of FIG. 12, a distance between the fuse 50 and the semiconductor substrate 100 is relatively long, thereby inhibiting a semiconductor structure positioned under the fuse 50 (e.g., a bit line 206 or the like) from being damaged.

Referring to FIG. 13, a first metal pattern 212 is formed as a fuse 50 (i.e., a fuse pattern 48), and the fuse 50 is linked to a bit line 206 through contact plugs 210. When a laser beam is irradiated into a fuse opening 226 to cut the fuse 50 in this case, a semiconductor structure positioned under the fuse 50 (e.g., the bit line 206) is damaged due to a relatively short distance between the fuse 50 and the bit line 206.

FIGS. 14 through 18 are cross-sectional views illustrating a method of cutting a fuse of a semiconductor device according to example embodiments of the inventive concepts.

Referring to FIG. 14, a first interlayer insulating layer 120 is formed on a substrate 100 to insulate the substrate 100 from a structure that is to be formed above the substrate 100. For example, an isolation layer 110 may be formed on the substrate 100, a gate electrode 111, a source region 112 and a drain region 13 of a transistor may be formed on the substrate 100, and the first interlayer insulating layer 120 may be formed on an entire surface of the substrate 100. The first interlayer insulating layer 120 may include at least one single layer selected from the group consisting of a boron phosphorous silicate glass (BPSG) layer, a phosphorous silicate glass (PSG) layer, a spin on glass (SOG) layer, a tetra ethyl ortho silicate (TEOS) layer and a undoped silicate glass (USG) layer, or a compound layer of the BPSG, PSG, SOG, TEOS and USG layers. An insulating material, such as silicon nitride, may be deposited to form the first interlayer insulating layer 120.

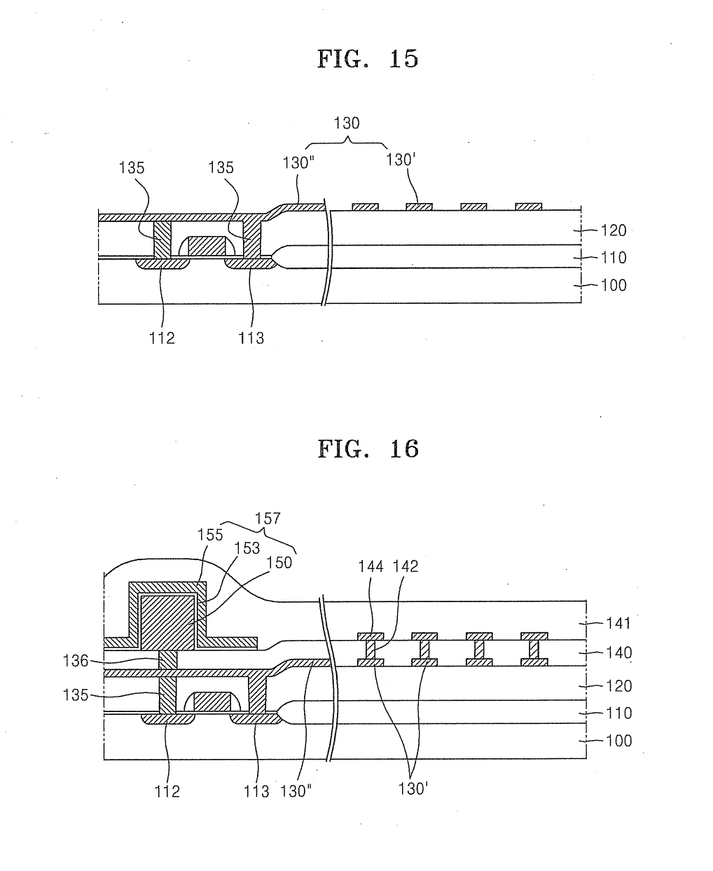

Referring to FIG. 15, the first interlayer insulating layer 120 is etched to form first contact plugs 135 that are connected to the drain region 113 and the source region 112, and a bit line 130. The first contact plugs 135 are formed using a stack layer including a conductive material (e.g., polycrystalline silicon doped with impurities, metal silicide, metal or polycrystalline silicon, and metal silicide).

The bit line 130 is divided into a bit line 130″ formed in a device formation region and bit lines 130′ formed in a fuse region. The bit line 130 may include at least one single layer selected from the group consisting of polycrystalline silicon, metal (e.g., tungsten, molybdenum or the like), conductive metal nitride (e.g., nitride titanium, nitride tantalum or the like) and metal silicide (e.g., tungsten silicide, cobalt silicide, or the like), or a compound layer of the polycrystalline silicon, the metal, the conductive metal nitride and the metal silicide.

Referring to FIG. 16, after the bit line 130 is formed, a second interlayer insulating layer 140 is formed above the substrate 100 and includes the bit line 130. The second interlayer insulating layer 140 may include at least one single layer selected from the group consisting of a BPSG layer, a PSG layer, an SOG layer, a TEOS layer and a USG layer, or a compound layer of the BPSG, PSG, SOG, TEOS and USG layers. Alternatively, the second interlayer insulating layer 140 may be formed of a single layer or a plurality of layers selected from the group consisting of combinations of the BPSG, PSG, SOG, TEOS and USG layers.

Second contact plugs 142 are formed in the second interlayer insulating layer 140 in the fuse region and connected to the bit lines 130′. First metal patterns 144 are formed on the second contact plugs 142. The first metal patterns 144 may be copper patterns or aluminum patterns. A contact plug 136 used for a lower electrode 150 is formed in the device formation region, and the lower electrode 150 is formed on the contact plug 136. The lower electrode 150 is shown as a simple stack type in FIG. 16 but may be a cylinder type, a fin type or the like.

A dielectric layer 153 and an upper electrode 155 are formed on an entire surface of the lower electrode 150 to form a capacitor 157. The bit line 130″ and the contact plug 136 are simultaneously shown in the cross-sectional view of FIG. 16 for understanding. However, the contact plug 136 is positioned on a different plane from the bit line 130″ and thus does not contact the bit line 130″.

A third interlayer insulating layer 141 is formed on the upper electrode 155 and the first metal patterns 144.

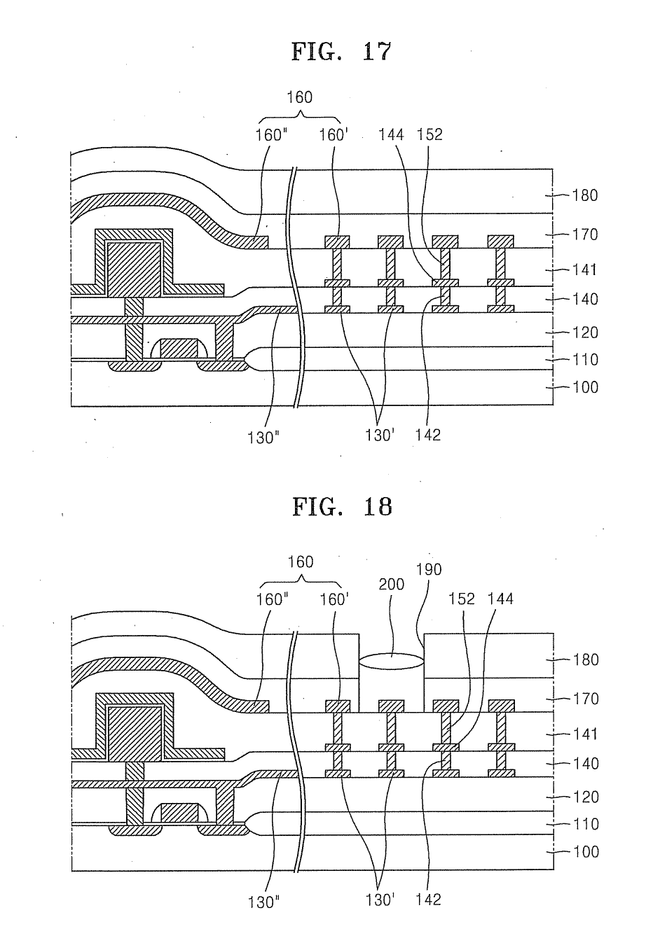

Referring to FIG. 17, second contact plugs 152 are formed in the third interlayer insulating layer 141. Second metal patterns 160 are formed on the third interlayer insulating layer 141 and the second contact plugs 152 and connected to the second contact plugs 152. In other words, some of the second metal patterns 160 operate as metal wires 160″, and the others of the second metal patterns 160 operate as fuse patterns 160′. The fuse patterns 160′ may be formed simultaneously with the metal wires 160″. The second metal patterns 160 may include one of aluminum (Al) or copper (Cu).

A passivation layer 170 and a polyimide layer 180 are formed on the second metal patterns 160. The passivation layer 170 and the polyimide layer 180 use a dielectric and buffering coating to prevent a chip from being scratched and to prevent penetration of moisture. The passivation layer 170 may be formed of a silicon nitride layer, a silicon oxide layer or a compound layer including the silicon nitride layer and the silicon oxide layer, wherein the silicon nitride layer and the silicon oxide layer have substantially high waterproof characteristics. This layer material absorbs mechanical, electrical and chemical shocks transmitted to a lower structure in a subsequent assembly or package process to protect internal semiconductor devices.

Referring to FIG. 18, the second metal patterns 160 may be positioned from a top of the semiconductor device to a substantially deep depth of the semiconductor device. If a layer (e.g., the passivation layer 170, the polyimide layer 180 or the like) is thickly formed on the fuse patterns 160′, a large amount of energy of a laser irradiated in order to cut a fuse is absorbed into the layer. Thus, a laser is to be irradiated for a long time to cut the fuse, which badly affects an adjacent fuse.

Therefore, the passivation layer 170 and/or the polyimide layer 180 are etched to form fuse openings 190 which expose upper surfaces of the fuse patterns 160′. A laser beam 200 may be irradiated into the fuse openings 190 to cut the fuse patterns 160′. When the fuse patterns 160′ are cut, the fuse patterns 160′ are connected to the bit line 130 through contact plugs 152 and 142, and the first metal patterns 144. A semiconductor structure positioned under the fuse patterns 160′ (e.g., the bit line 130 or the like) is inhibited from being damaged due to a relatively long distance between the fuse patterns 160′ and the semiconductor substrate 100.

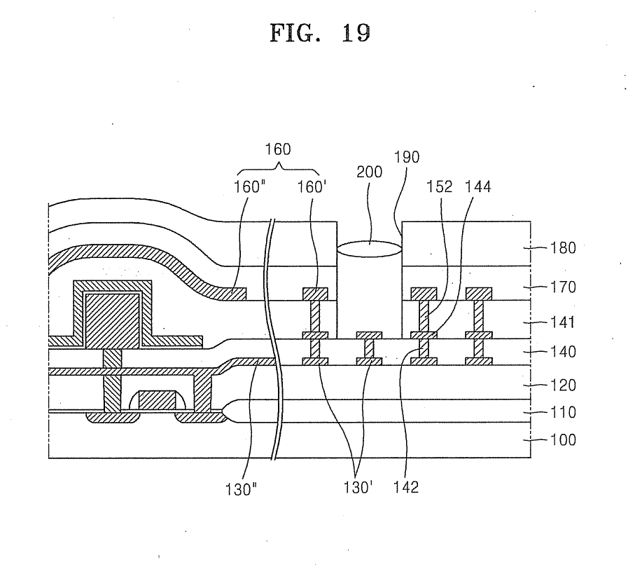

FIG. 19 is a cross-sectional view illustrating a method of cutting a fuse of a semiconductor device according to example embodiments of the inventive concepts.

The method of FIG. 19 is the same as that of FIG. 18 except that first metal patterns 144 are formed as fuse patterns. A passivation layer 170, a polyimide layer 180, an interlayer insulating layer 141 and the like are etched to form fuse openings 190 that expose upper surfaces of the fuse patterns 144. A laser beam 200 may be irradiated into the fuse openings 190 to cut the fuse patterns 144. When the fuse patterns 144 are cut, the fuse patterns 144 are connected to a bit line 130 through contact plugs 142. A semiconductor structure positioned under the fuse patterns 144 (e.g., the bit line 130 or the like) is inhibited from being damaged due to a relatively long distance between the fuse pattern 144 and a semiconductor substrate 100.

While the inventive concepts has been particularly shown and described with reference to example embodiments thereof, it will be understood that various changes in form and details may be made therein without departing from the spirit and scope of the following claims.

1-12. (canceled)

13. A method of cutting a fuse of a semiconductor device, comprising:
forming a first interlayer insulating layer on a semiconductor substrate;
forming a plurality of fuse patterns on the first interlayer insulating layer, wherein each of the fuse patterns includes a fuse connected to the semiconductor substrate;
forming a second interlayer insulating layer on the fuse patterns, wherein the second interlayer insulating layer includes a plurality fuse openings that each correspond to one of the fuse patterns, the fuse openings exposing the fuse in the corresponding fuse pattern; and
cutting one of the fuses by irradiating laser beams through the corresponding fuse opening, when the plurality of fuse patterns is connected to the semiconductor substrate.

14. The method of claim 13, wherein forming the plurality of fuse patterns includes connecting the plurality of fuse patterns to an active region formed in the semiconductor substrate.

15. The method of claim 13, wherein the plurality of fuse patterns are formed as a plurality of metal patterns on the first interlayer insulating layer.

16. The method of claim 13, wherein forming the plurality of fuse patterns includes:
forming a plurality of first metal patterns on the first interlayer insulating layer;
forming a third interlayer insulating layer on the plurality of first metal patterns; and
forming a plurality of second metal patterns on the third interlayer insulating layer, wherein the plurality of fuse patterns is formed as the plurality of second metal patterns.

17. The method of claim 16, wherein the plurality of fuse patterns are formed as the plurality of first and second metal patterns.

18. The method of claim 13, further comprising:
forming a plurality of contact plugs in the first interlayer insulating layer; and
connecting the plurality of fuse patterns to the semiconductor substrate through the plurality of contact plugs.

19. The method of claim 13, wherein the plurality of fuse patterns are parallel with one another in a first direction in a fuse region of the semiconductor substrate and are spaced apart from one another in a second direction perpendicular to the first direction.

20. The method of claim 19, wherein the fuses in the plurality of fuse patterns adjacent to one another and parallel with one another in the second direction.

21. The method of claim 19, wherein the fuses in the plurality of fuse patterns are not directly adjacent to one another and are in a zigzag faun in the second direction.

22. A method of cutting a fuse of a semiconductor device, comprising:
forming a semiconductor substrate that includes a fuse region;
forming a plurality of fuse patterns in the fuse region of the semiconductor substrate, each of the fuse patterns includes a fuse;
forming an interlayer insulating layer that insulates the plurality of fuse patterns from the semiconductor substrate; and
cutting one of the fuses by irradiating laser beams through the corresponding fuse opening, when the plurality of fuse patterns are connected to the semiconductor substrate.

23. The method of claim 22, further comprising connecting the plurality of fuse patterns to an active region in the semiconductor substrate.

24. The method of claim 22, further comprising forming a plurality of contact plugs in the interlayer insulating layer, wherein the plurality of fuse patterns are connected to the semiconductor substrate through the plurality of contact plugs.
